(19) United States
(12) Patent Application Publication
(10) Pub. No.: US 2026/0104450 A1
(43) Pub. Date: Apr. 16, 2026

(54) ON-CHIP STRESS DETERMINATION AND COMPENSATION

(71) Applicant: TEXAS INSTRUMENTS INCORPORATED, Dallas, TX (US)

(72) Inventors: Divya KAUR, Delhi (IN); Vinod MENEZES, Bangalore (IN); Raja SELVARAJ, Bangalore (IN); Tobias Bernhard FRITZ, Mainburg (DE); Keith R. GREEN, McKinney, TX (US)

(21) Appl. No.: 18/915,136

(22) Filed: Oct. 14, 2024

(51) Int. Cl. G01R 31/28; H01L 21/66

(52) U.S. Cl. CPC G01R 31/2896; G01R 31/2856; H10P 74/273

(57) ABSTRACT

In some examples, a circuit includes a first electrical component disposed in a first region of a substrate. The circuit also includes a first measurement circuit disposed in the first region proximate to the first electrical component. The circuit also includes a second electrical component disposed in a second region of the substrate, the second region of the substrate proximate to the first region of the substrate. The circuit also includes a second measurement circuit disposed in the second region proximate to the second electrical component. The circuit also includes a stress induction device disposed on the substrate above the second region.

### BACKGROUND

Components of a circuit, such as may be implements on a semiconductor die, may operate differently under different physical or mechanical stress. This variation in operation may be challenging to characterize and/or correct post-packaging of the semiconductor die SUMMARY

In some examples, a circuit includes a first electrical component disposed in a first region of a substrate. The circuit also includes a first measurement circuit disposed in the first region proximate to the first electrical component. The circuit also includes a second electrical component disposed in a second region of the substrate, the second region of the substrate proximate to the first region of the substrate. The circuit also includes a second measurement circuit disposed in the second region proximate to the second electrical component. The circuit also includes a stress induction device disposed on the substrate above the second region.

In some examples, a circuit includes a first electrical component disposed in a first region of a substrate, wherein the first region is under mechanical stress applied to the first region. The circuit also includes a second electrical component disposed in a second region of the substrate, the second region of the substrate proximate to the first region of the substrate but outside of the first region. The circuit also includes a measurement circuit coupled to the first electrical component and the second electrical component.

In some examples, a method includes disposing a first electrical component in a first region of a substrate. The method also includes disposing a second electrical component in a second region of the substrate proximate to the first region. The method also includes disposing a measurement circuit coupled to at least one of the first electrical component or the second electrical component. The method also includes disposing a stress induction device on the substrate above the first region.

### BRIEF DESCRIPTION OF THE DRAWINGS

FIG. 1 shows a block diagram of a system in accordance with various examples.

FIG. 2 shows a cross-sectional diagram of a semiconductor die in accordance with various examples.

FIG. 3 shows a schematic diagram of a stress measurement circuit in accordance with various examples.

FIG. 4 shows a schematic diagram of a stress measurement circuit in accordance with various examples.

FIG. 5 shows a schematic diagram of a stress measurement circuit in accordance with various examples.

FIG. 6 shows a diagram of signal waveforms in a voltage reference circuit in accordance with various examples.

FIG. 7 shows is a flowchart of a method of performing on-chip stress determination and/or compensation in accordance with various examples.

### DETAILED DESCRIPTION

Physical or mechanical stress or strain, which may be generalized as stress, may adversely affect a circuit. For example, as stress exerted on a circuit increases, an error between a nominal or expected output value of the circuit and an actual output value of the circuit may increase. This increase in error may be in addition to other error sources, such as temperature, noise, process variation, or the like. In some system implementations, this error may be tolerable. However, in other system implementations, the error may render the circuit unsuitable for use in the system. An example of one such system is a high-precision voltage reference. To mitigate these errors, various approaches may be explored to measure or determine the error and compensate or correct for the error. For example, measurements may be performed to determine a stress placed on a circuit and, in some examples, a compensation or corrective value or signal may be determined to compensate for the determined stress. In some examples, the determined compensation is applied to a signal chain of the circuit to compensate for effects of the stress on an output signal of the circuit.

Examples of this description include a circuit having on-chip stress determination and, in some examples, stress compensation. To perform the stress determination, an amount of stress placed on a circuit may be characterized based on a reference element. For example, various electrical components may have respective stress sensitivities. Some electrical components are more sensitive to stress than others. To determine the effects of stress on an electrical component, a stress may be artificially imposed on the electrical component. For example, an on-die stress zone may be created via any combination (e.g., one or more of) of a bond wire, a bond pad, a via, a Polyamide layer, a Damascene Copper layer, and/or the like to create and/or concentrate stress on a designated region of the die. By including a reference element in this designated region of the die, effects of the stress on the reference element may be determined or estimated. For reference elements positioned proximate to a production component (e.g., an electrical component that is in the signal chain of the circuit and for which the effects of stress are to be compensated), the effects of the stress on the reference element may approximate how the production component will react under stress. Thus, compensation for the production component may be determined based on the measured response of the reference element in the presence of the applied stress. In some examples, the determined compensation is stored and/or provided to another component. In other examples, the compensation is applied to a signal chain of the circuit to compensate for the effects of the stress on the production component.

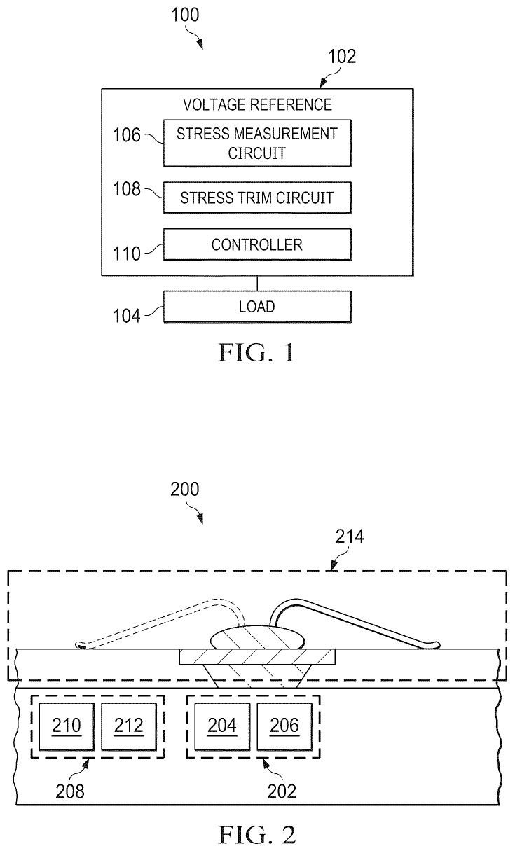

FIG. 1 is a block diagram of an example system 100. In some examples, the system 100 is suitable for implementation in any device to provide a voltage reference signal (Vref). In other examples, the system 100 may be suitable for implementation in an analog to digital converter, a digital to analog converter, an oscillator, or the like. Taking an implementation of the system 100 in a device to provide Vref as an example, a voltage reference circuit 102 provides Vref to a load 104. The load 104 may be any suitable circuit or device, the scope of which is not limited herein. In some examples, the load 104 may be sensitive to variation in values of Vref. For example, variations in Vref may affect operation of the load 104 such that the variations in Vref render the load 104 unsuitable for an intended purpose. The variation may result from temperature, solder shift, long term drift (LTD), such as resulting from stress to which the voltage reference circuit 102 is subjected, process variation, or any other error sources.

To mitigate effects of the variation, the voltage reference circuit 102 may include one or more circuits to perform measurement and/or compensation for the variation. For example, to at least partially mitigate the effects of the variations resulting from stress to which the voltage reference circuit 102 is subjected, the voltage reference circuit 102 may include one or more of a stress measurement circuit 106, a stress trim circuit 108, and/or a controller 110. In some examples, the stress measurement circuit 106 measures, estimates, or otherwise provides a signal having a value representative of a stress or stress to which the voltage reference circuit 102 is subjected. For example, the stress measurement circuit 106 may include a device under stress and a device not under stress. The device under stress may be under both an inherent stress occurring on a semiconductor die in or on which the device under stress is disposed (such as due to the manufacturing process), as well as an imposed stress. The device not under stress may also be under the inherent stress occurring on the semiconductor die in or on which the device not under stress is disposed but may not be exposed to the imposed stress. Because the inherent stress occurring on the semiconductor die is shared between both devices, the inherent stress may be ignored.

The imposed stress may be artificially created on the semiconductor die, such as via metallization, bond wires, vias, or the like. Through these structures, the imposed stress may be focused on the device under stress. In this way, a first region, or stress zone, is formed beneath the structures causing the imposed stress, the first region including the device under stress, and a second region, or non-stress zone, is formed including the device not under stress. In some examples, the device under stress and the device not under stress may each be implemented as Zener diodes, such as buried Zener diodes. In other examples, the device under stress and the device not under stress are implemented as any other suitable device, such as another form of diode, a resistor, a transistor (e.g., bi-polar junction transistor (BJT) or field effect transistor (FET)), or any other semiconductor device. In some examples, the Zener diodes of the device under stress and the device not under stress have characteristics within a threshold variance of one another. In some examples, the stress measurement circuit 106 further includes a measurement circuits or stress gauges proximate to each of the device under stress and the device not under stress. For example, a first measurement circuit may be disposed in the first region proximate to the device under stress and a second measurement circuit may be disposed in the second region proximate to the device not under stress. In some examples, the first and second measurement circuits are each implemented as resistors having characteristics within a threshold variance of one another. The first measurement circuit measures a voltage of the device under stress in response to an input signal and the second measurement circuit measures a voltage of the device not under stress in response to the input signal.

By determining a difference between an output signal of the first measurement circuit and an output signal of the second measurement circuit, an effect of stress on the voltage reference circuit 102 may be estimated. For example, the controller 110 may receive the output signals of the first and second measurement circuits and may determine the difference between the received output signals. Based on this difference, the controller 110 may be determine a trim or compensation value to compensate for the effect of stress on the voltage reference circuit 102. In some examples, the controller 110 controls the stress trim circuit 108 to compensate for the effect of stress on the voltage reference circuit 102. For example, based on the determined difference, the controller 110 controls the stress trim circuit 108 to increase or decrease a value of a signal, such as a voltage or current, provided in the voltage reference circuit 102. In some examples, the controller 110 controls the stress trim circuit 108 directly based on the determined difference. In other examples, the controller 110 determines a control value for controlling the stress trim circuit 108 by performing a lookup in a table or other database based on the determined difference to determine a control value corresponding to the determined difference. In yet other examples, at least some components of the stress measurement circuit 106 and the stress trim circuit 108 may be combined such that an output signal of the combined circuit is compensation value.

FIG. 2 is a cross-sectional diagram of an example semiconductor die 200. In some examples, the semiconductor die 200 includes a voltage reference circuit 102, as described above. Accordingly, at least some components of the voltage reference circuit 102 are not show in FIG. 2. In an example, the semiconductor die 200 includes a first region 202 in which a first electrical component 204 and a first measurement circuit 206 are disposed. The semiconductor die 200 also includes a second region 208 in which a second electrical component 210 and a second measurement circuit 212 are disposed. In an example, a stress induction device 214 is disposed above the first region. In various examples, the stress induction device 214 includes one or more of a bond wire, a bond pad, a via, metallization (e.g., such as a Polyamide layer, or a Damascene Copper layer, Aluminum, or the like), etc. The stress induction device 214 provides an artificially created mechanical stress on components disposed in the first region, placing those components (e.g., the first electrical component 204 and the first measurement circuit 206) under stress. As described above herein, that stress causes variation in performance of the first electrical component 204 and the first measurement circuit 206 in comparison to the second electrical component 210 and second measurement circuit 212, respectively.

In some examples, the second electrical component 210 has characteristics within a threshold variance of the first electrical component 204. In this way, the first and second electrical components may be considered replica devices of one another. Similarly, the second measurement circuit 212 has characteristics within a threshold variance of the first measurement circuit 206. In this way, the first and second measurement circuits may be considered replicas of one another. As a result, performance, such as reflected in output signals, of the first electrical component 204 and the second electrical component 210 may be compared or otherwise analyzed to determine an effect of stress provided by the stress induction device 214 on the first electrical component 204.

A piezo-sensitive electrical component or material may be used in the circuit as a stress sensor (e.g., the first electrical component 204 and/or the second electrical component 210). In an example, a Buried Zener (BZ) diode may be used to determine the effects of stress on a circuit. For example, a voltage (V_{BZ}) provided at the cathode of a BZ diode under stress may be approximated by the following equation 1 in which V_{BZ0} is a voltage of a stress-insensitive diode (e.g., a BZ diode not under stress, having characteristics within a threshold variance of the BZ diode under stress, and located proximate to the BZ diode under stress), σ characterizes an amount of stress placed on the BZ diode, and β is a stress sensitivity of the BZ diode.

$${V}_{BZ} = {V}_{BZ 0} ( 1 + β * σ ) \qquad ( 1 )$$

By determining σ in the above equation 1, the effect of stress on the BZ diode under stress may be determined. Compensation for this determined stress may then be determined according to the following equation 2 in which α is a stress sensitivity of a first resistor having resistance R_{SG}, and R_{SG0} is a resistance of a second resistor that is approximately equal to R_{SG} for the condition σ=0.

$${R}_{SG} = {R}_{SG 0} ( 1 + α * σ ) \qquad ( 2 )$$

In an example, based on the above equations 1 and 2, a stress invariant bias current, Isg, may be determined to provide a compensation signal for the stress. Isg is shown below in equation 3.

$$I s g = ( {V}_{BZ 0} * β ) / ( {R}_{SG0} * α ) \qquad ( 3 )$$

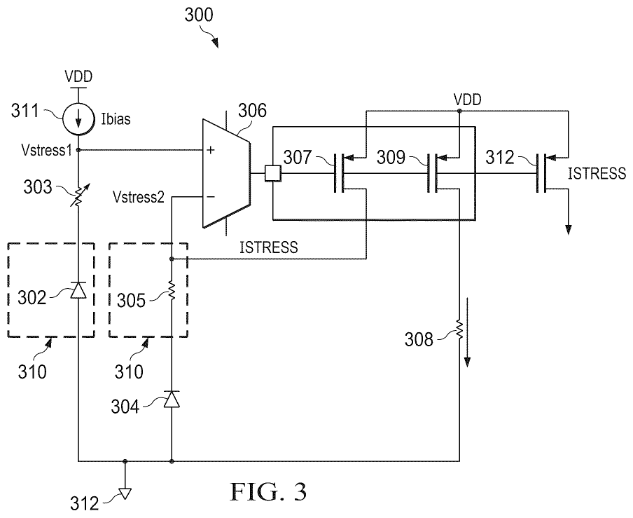

FIG. 3 is a schematic diagram of an example stress measurement circuit 300. In an example, the stress measurement circuit 300 is suitable for implementation as the stress measurement circuit 106 of FIG. 1. In some examples, the stress measurement circuit 300 additionally includes trim or correction components such that the stress measurement circuit 300 is suitable for implementation as both the stress measurement circuit 106 and the stress trim circuit 108, each of FIG. 1. In an example, the stress measurement circuit 300 includes a Zener diode 302, a variable resistor 303, a Zener diode 304, a resistor 305, an amplifier 306, a transistor 307, a resistor 308, a transistor 309, a current source 311, and a transistor 312. In an example architecture of the stress measurement circuit 300, a stress induction device 310 is disposed above the Zener diode 302 and resistor 305. As such, the Zener diode 302 may be the device under stress, such as described above. Correspondingly, the Zener diode 304 may be the device not under stress, also as described above. The Zener diode 302 has an anode coupled to a ground terminal 313 and has a cathode. The Zener diode 304 has an anode coupled to the ground terminal 313 and has a cathode. The variable resistor 303 has a first terminal coupled to the anode of the Zener diode 302 and has a second terminal. The variable resistor 303 also has a control terminal (not shown) at which a value may be provided for controlling a resistance of the variable resistor 303. In some examples, the value may be provided by a controller, a digital state machine, a storage device (e.g., a programmable memory), or the like, the scope of which is not limited herein. The resistor 305 has a first terminal coupled to the anode of the Zener diode 304 and has a second terminal. The amplifier 306 has a first input terminal (e.g., a non-inverting input terminal) coupled to the second terminal of the variable resistor 303, a second input terminal (e.g., an inverting input terminal) coupled to the second terminal of the resistor 305, and has an output terminal. The transistor 307 has a first terminal coupled to a terminal (not shown) at which a supply voltage (VDD) is provided, a second terminal coupled to the second input terminal of the amplifier 306, and a control terminal coupled to the output terminal of the amplifier 306. The transistor 309 has a first terminal coupled to the terminal at which VDD is provided, has a second terminal, and has a control terminal coupled to the output terminal of the amplifier 306. The transistor 312 has a first terminal coupled to the terminal at which VDD is provided, has a second terminal, and has a control terminal coupled to the output terminal of the amplifier 306. The resistor 308 is coupled between the second terminal of the transistor 309 and the ground terminal 313. The current source 311 has a first terminal coupled to the terminal at which VDD is provided and has a second terminal coupled to the first input terminal of the amplifier 306.

In some examples, the second terminal of the transistor 312 may be coupled to a circuit or component, such as the stress trim circuit 108, for providing stress compensation to mitigate effects of stress on the Zener diode 304 (or other components of a device including the stress measurement circuit 300) as approximated by the determined effects of the stress induction device 310 on performance of the Zener diode 302. For example, the second terminal of the transistor 312 may be coupled to a signal path of a component (not shown) for which stress trim is to be provided through a variable resistor (not shown). Istress flows through the variable resistor into the signal path of the component for which stress trim is to be provided. A value of resistance of the variable resistor is modified by a controller or other component to cause a voltage drop of the variable resistor to approximately equal a voltage shift of the voltage response of the Zener diode 302 in comparison to the voltage response of the Zener diode 304. Because the voltage shift is caused at least in part by the stress induced by the stress induction device 310, the resulting voltage and current injected into the signal path of the component for which stress trim is to be provided through the variable resistor at least partially mitigates the effects of stress on performance of the component for which stress trim is to be provided.

In an example of operation of the stress measurement circuit 300, a voltage response of the Zener diode 302 differs from that of the Zener diode 304 resulting from the stress imposed on the Zener diode 302 by the stress induction device 310. The amplifier 306 provides a current signal (Istress) representative of a voltage difference between the voltage response of the Zener diode 302 in the presence of the imposed stress and the voltage response of the Zener diode 302 in the absence of the imposed stress. In some examples, Istress may be indicative of a compensation value for compensating for stress in the voltage reference circuit 102. In another example, Istress may quantify an effect of the stress imposed on the Zener diode 302 stress induction device 310 (e.g., be representative of an amount of the stress imposed on the Zener diode 302 by the stress induction device 310 and to which the Zener diode 304 is not exposed). For example, Istress, or a signal indicative of Istress, may be injected into a signal path of the voltage reference circuit 102 to compensate for effects of stress to which the voltage reference 102 is subjected. In some examples, a voltage provided at the cathode of the Zener diode 302 may be approximated by equation 1, as shown above, in which V_{BZ} is the voltage of the Zener diode 302, V_{BZ0} is the voltage of the Zener diode 304, Δσ characterizes an amount of stress placed on the Zener diode 302 by way of the stress induction device 310, β is a stress sensitivity of the Zener diode 302, and R1 is a resistance of the resistor 308. A stress-to-current relation of the stress measurement circuit 300 may then be approximated by the following equation 4, where variables have the same values as described above for approximating the voltage provided at the cathode of the Zener diode 302.

$$Istress = ( {V}_{BZ 0} * β * Δ σ ) / R 1 \qquad ( 4 )$$

In an example, to compensate for the effects of stress on the Zener diode 302 a resistance of the variable resistor 303 may be modified until Istress equals Ibias, which is a current provided by the current source 311. For example, the resistance of the variable resistor 303 may be modified such that the following equations (5) and (6) are true, in which Rtrim is the resistance of the variable resistor 303 and Rstress is the resistance of the resistor 305.

$${V}_{BZ} + Ibias * Rtrim = {V}_{BZ 0} + ( Rstress ) * Ibias \qquad ( 5 )$$

$${V}_{BZ} - {V}_{BZ 0} = Ibias * ( Rstress - Rtrim ) \qquad ( 6 )$$

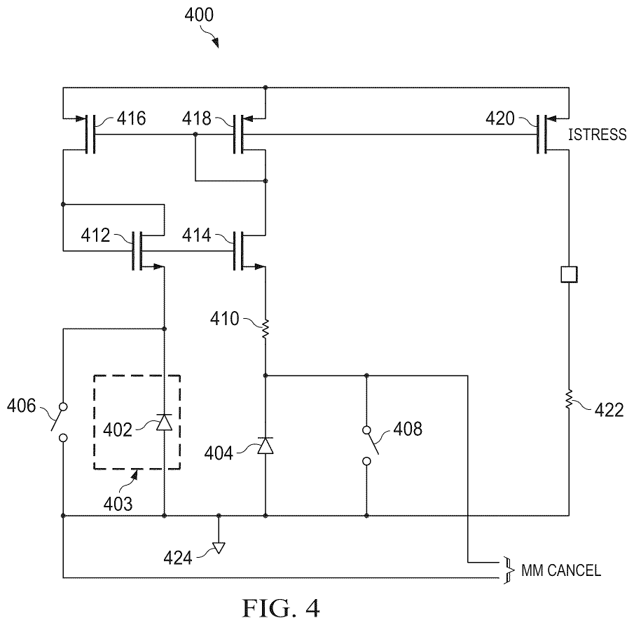

FIG. 4 is a schematic diagram of an example stress measurement circuit 400. In an example, the stress measurement circuit 400 is suitable for implementation as the stress measurement circuit 104 of FIG. 1. In an example, the stress measurement circuit 400 includes a Zener diode 402, a Zener diode 404 a switch 406, a switch 408, a resistor 410, a transistor 412, a transistor 414, a transistor 416, a transistor 418, a transistor 420, and a resistor 422.

In an example architecture of the stress measurement circuit 400, the Zener diode 402 has an anode coupled to a ground terminal 424, and has a cathode. The Zener diode 404 has an anode coupled to the ground terminal 424, and has a cathode. The switch 406 has a first terminal coupled to the cathode of the Zener diode 402 and a second terminal coupled to the ground terminal 424. The switch 408 has a first terminal coupled to the cathode of the Zener diode 404 and a second terminal coupled to the ground terminal 424. The resistor 410 has a first terminal coupled to the cathode of the Zener diode 404, and has a second terminal. The transistor 412 has a first terminal, a second terminal coupled to the cathode of the Zener diode 402, and has a control terminal coupled to the first terminal of the transistor 412. The transistor 414 has a first terminal, a second terminal coupled to the second terminal of the resistor 410, and has a control terminal coupled to the control terminal of the transistor 412. The transistor 416 has a first terminal, has a second terminal coupled to the first terminal of the transistor 412, and has a control terminal coupled to the first terminal of the transistor 414. The transistor 418 has a first terminal coupled to the first terminal of the transistor 416, a second terminal coupled to the first terminal of the transistor 414, and a control terminal coupled to the control terminal of the transistor 416. The transistor 420 has a first terminal coupled to the first terminal of the transistor 416, a second terminal, and has a control terminal coupled to the control terminal of the transistor 416. The resistor 422 is coupled between the second terminal of the transistor 420 and the ground terminal 424.

In an example of operation of the stress measurement circuit 400, a voltage response of the Zener diode 402 differs from that of the Zener diode 404 resulting from stress imposed on the Zener diode 402 by a stress induction device 403. Because a voltage response of a Zener diode increases as the stress on the Zener diode increases, a voltage response of the Zener diode 402 (V_{BZ402}) is greater in value than a voltage response of the Zener diode 404 (V_{BZ404}). The transistors 412, 414 form a common gate structure such that the transistors 412, 414, 416, 418 for a closed loop amplifier with an output current replicated by the transistor 420 as Istress. As a result, Istress may be approximated according to the above equation (4) with V_{BZ0} being the voltage of the Zener diode 404, Δσ characterizes an amount of stress placed on the Zener diode 402 by way of the stress induction device 403, β is a stress sensitivity of the Zener diode 402, and R1 is a resistance of the resistor 410. The resistor 422 functions as a scaling factor such that a voltage provided at the drain of the transistor 420 is approximately equal to R422*(V_{BZ}−V_{BZ0}/R410), where R422 is a resistance of the resistor 422 and R410 is a resistance of the resistor 410. In an example, a mismatch among the transistors 412, 414, 416, 418, and/or 420 may be calibrated or compensated for via a signal MM cancel. In some examples, the switches 406, 408 may be closed to determine a value of Istress resulting from mismatch of the transistors 412, 414, 416, 418, 420 and without regard to the Zener diodes 402, 404 (e.g., such as by grounding both anode and cathode of the Zener diodes 402, 404, effectively removing their influence from the stress measurement circuit 400. This value of Istress may be provided to a controller, digital state machine, or other component for determining and providing MM cancel to mitigate effects of the mismatch. The switches 406, 408 may be opened during normal operation of the stress measurement circuit 400, such as while determining an effect of the stress induction devices 403 on performance of the Zener diode 402. The switches 406, 408 may be controlled by any suitable device, the scope of which is not limited herein, such as, for example, the controller, digital state machine, or other component that determines and provides MM cancel.

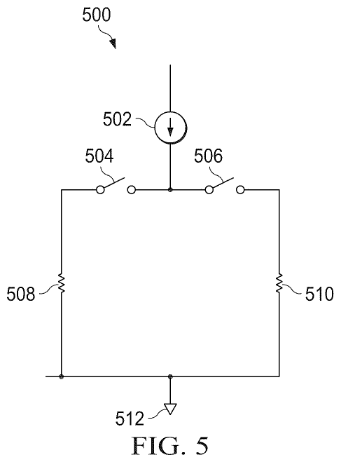

FIG. 5 is a schematic diagram of an example stress measurement circuit 500. In an example, the stress measurement circuit 400 is suitable for implementation as the stress trim circuit 108 of FIG. 1. In an example, the stress measurement circuit 500 includes a current source 502, a switch 504, a switch 506, a resistor 508, and a resistor 510. In an example architecture of the stress measurement circuit 500, the current source 502 has a first terminal coupled to a power supply (not shown), and has a second terminal. The switch 504 has a first terminal coupled to the second terminal of the current source 502, and has a second terminal. The switch 506 has a first terminal coupled to the second terminal of the current source 502, and has a second terminal. The switch 504 and the switch 506 may also each have respective control terminals (not shown) coupled to any suitable component (such as an analog and/or digital controller, a state machine, or the like) for controlling an open/closed state of the switches 504, 506. The resistor 508 is coupled between the second terminal of the switch 504 and a ground terminal 512. The resistor 510 is coupled between the second terminal of the switch 506 and the ground terminal 512.

In an example of operation of the stress measurement circuit 500, a voltage response of the resistor 508 differs from that of the resistor 510 resulting from stress imposed on the resistor 508 by a stress induction device 509. During a first time, the switch 504 is closed and the switch 506 is opened such that a bias current provided by the current source 502 flows through the resistor 508. Subsequently, at a second time, the switch 504 is opened and the switch 506 is closed such that the bias current provided by the current source 502 flows through the resistor 510. The switches 504, 506 may be controlled by any suitable source (not shown), such as a controller, programmable memory, digital device, or the like. In an example, an effect of the stress induction device 509 on the resistor 508 may be quantified by subtracting a voltage drop across the resistor 510 from a voltage drop across the resistor 508.

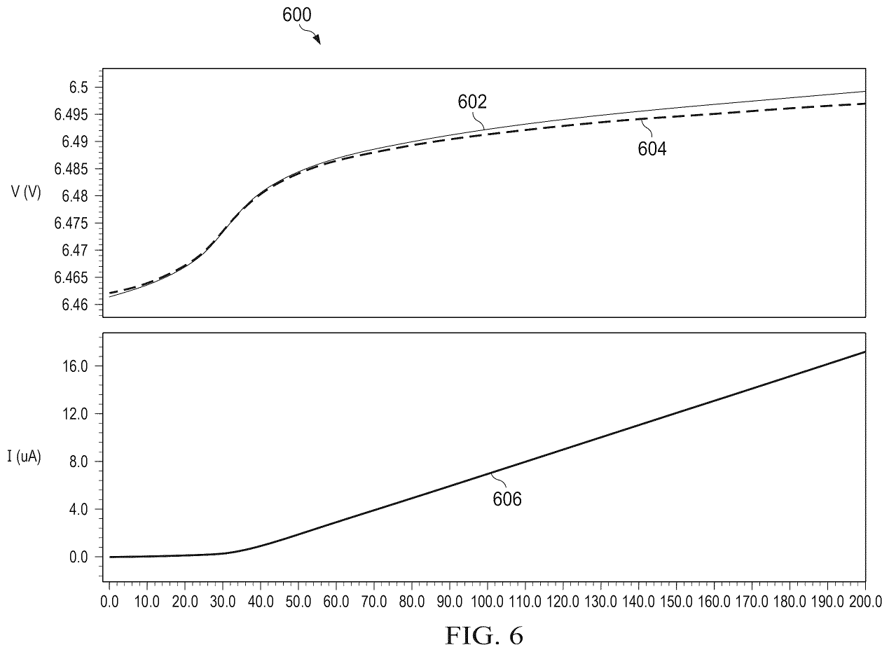

FIG. 6 is a diagram 600 of signal waveforms in an example voltage reference circuit 102. The diagram 600 includes a signal 602 representative of a voltage of a device under stress and a signal 604 representative of a voltage of a device not under stress, each as described above herein. The diagram 600 also includes a signal 606 representative of a difference between the signals 602 and 604. For example, the signal 606 may be determined at least in part based on a difference between the signals 602 and 604. The signals 602, 604 are shown having a horizontal axis representative of time and a vertical axis representative of voltage in units of volts (V). The signal 606 has a horizontal axis representative of time and a vertical axis representative of current in units of microamperes (uA).

As shown by the signal 602 and as described above herein, responsive to the device under stress being subjected to stress, a voltage response of the device under stress varies from that of a device not under stress, such as shown by the signal 604. As shown by the signal 604, responsive to an increase in variance between the signals 602 and 604, the signal 606 increases in value, indicating a greater amount of compensation for compensating for the stress causing the variance between the signals 602, 604.

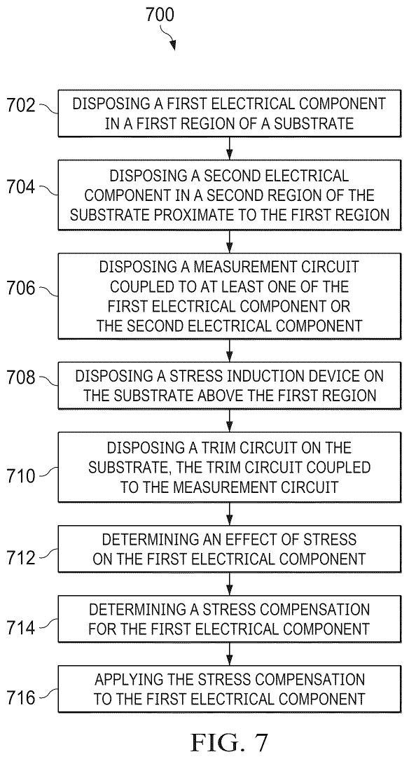

FIG. 7 is a flowchart of an example method 700 of performing on-chip stress determination and/or compensation. In an example, the method 700 is performed by the system 100, such as via the voltage reference circuit 102. For example, the method 700 may be performed by one or more of the stress measurement circuit 106, stress trim circuit 108, and/or controller 110. By executing operations of the method 700, the voltage reference circuit 102 may determine or estimate an effect of stress or stress on components of the voltage reference circuit 102 and determine a value of a signal for compensating for that effect of stress or stress on components of the voltage reference circuit 102.

At operation 702, the method 700 includes disposing a first electrical component in a first region of a substrate.

At operation 704, the method 700 includes disposing a second electrical component in a second region of the substrate proximate to the first region. The second electrical component has characteristics within a threshold variance of the first electrical component. In this way, the first and second electrical components may be considered replica devices of one another. In some examples, the first and second electrical components are buried Zener diodes. In other examples, the first and second electrical components are any other suitable components that have a nonzero stress sensitivity, the scope of which is not limited herein.

At operation 706, the method 700 includes disposing a measurement circuit coupled to at least one of the first electrical component or the second electrical component. In some examples, the measurement circuit is a stress gauge, such as a resistor. In some examples, the method also comprises disposing a second measurement circuit proximate to the second electrical component, the second measurement circuit coupled to the second electrical component. In such examples, the second measurement circuit has characteristics within a threshold variance of the first measurement circuit. In this way, the first and second measurement circuits may be considered replicas of one another.

At operation 708, the method 700 includes disposing a stress induction device on the substrate above the first region. In some examples, the stress induction device includes one or more of a bond wire, a bond pad, a via, metallization such as aluminum, a Polyamide layer, or a Damascene Copper layer. In this way, the first region is a stressed region in which an artificial or manufactured mechanical stress is imposed on the components disposed in the first region.

At operation 710, the method 700 includes disposing a trim circuit on the substrate, the trim circuit coupled to the measurement circuit. The trim circuit is any circuit suitable capable of providing a current and/or voltage signal based on a determined compensation value. The compensation value may be determined to compensate for or at least partially mitigate effects of the stress induction device on the components disposed in the first region.

At operation 712, the method 700 includes determining an effect of stress on the first electrical component. In some examples, the effect of stress on the first electrical component is determined based on a comparison of output signals of the first and second electrical components. For example, because the first and second electrical devices are replica devices and are located proximate to one another, variation in values of output signals of the first and second electrical devices may be attributable to the effect of stress on the first electrical component. Thus, by comparing the output signals of the first and second electrical components to determine a difference between the output signals of the first and second electrical components, the effect of the stress may be determined.

At operation 714, the method 700 includes determining a stress compensation for the first electrical component. In some examples, determining the stress compensation include indexing into a lookup table or other database based on the difference determined at operation 712 to determine the stress compensation. In other examples, the difference determined at operation 712 is itself the stress compensation. In yet other examples, a current source may be controlled based on the determined difference or other control value determined based on the output signal of the first electrical component and/or the second electrical component. The current source may provide the stress compensation based on the control.

At operation 716, the method 700 includes applying the stress compensation to the first electrical component. In some examples, applying the stress compensation includes providing the stress compensation to a trim circuit of other circuit suitable for compensating for the effect of stress on the first electrical component and/or the voltage reference circuit. In some examples, the trim circuit includes a resistor through which a current determined as the stress compensation flows.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. A circuit, comprising:
a first electrical component disposed in a first region of a substrate;
a first measurement circuit disposed in the first region proximate to the first electrical component;
a second electrical component disposed in a second region of the substrate, the second region of the substrate proximate to the first region of the substrate;
a second measurement circuit disposed in the second region proximate to the second electrical component; and
a stress induction device disposed on the substrate above the second region.

2. The circuit of claim 1, wherein the stress induction device includes a bond pad and a plurality of vias.

3. The circuit of claim 2, wherein the stress induction device includes a bond wire coupled to the bond pad.

4. The circuit of claim 1, wherein the stress induction device is not above the first region.

5. The circuit of claim 1, wherein the second electrical component has characteristics within a threshold variance of the first electrical component, and wherein the second measurement circuit has characteristics within a threshold variance of the first measurement circuit.

6. The circuit of claim 1, further comprising:
a third electrical component disposed in a third region of the substrate;
a third measurement circuit disposed in the third region proximate to the third electrical component;
a fourth electrical component disposed in a fourth region of the substrate, the fourth region of the substrate proximate to the third region of the substrate;
a fourth measurement circuit disposed in the fourth region proximate to the first electrical component; and
a second stress induction device disposed on the substrate above the fourth region, wherein the first and second regions of the substrate are in a first stress zone, and the third and fourth regions of the substrate are in a second stress zone separate from the first stress zone.

7. The circuit of claim 6, wherein the first electrical component and the second electrical component are each semiconductor devices.

8. A circuit, comprising:
a first electrical component disposed in a first region of a substrate, wherein the first region is under mechanical stress applied to the first region;
a second electrical component disposed in a second region of the substrate, the second region of the substrate proximate to the first region of the substrate but outside of the first region; and
a measurement circuit coupled to the first electrical component and the second electrical component.

9. The circuit of claim 8, wherein the first electrical component and the second electrical component are each semiconductor devices.

10. The circuit of claim 8, wherein further comprising a variable resistor having first and second terminals, a resistor having first and second terminals, a current source having first and second terminals, and an amplifier having first and second inputs and having first and second output terminals, wherein the measurement circuit includes a differential amplifier, the first electrical component has a first terminal coupled to a ground terminal of the circuit and a second terminal coupled to the first terminal of the variable resistor, the second terminal of the variable resistor is coupled to a first input terminal of the differential amplifier, the first terminal of the current source is coupled to a voltage supply terminal and the second terminal of the current source is coupled to the first input terminal of the differential amplifier, the second electrical component has a first terminal coupled to the ground terminal of the circuit and a second terminal coupled to the first terminal of the resistor, the second terminal of the resistor is coupled to a second input terminal of the differential amplifier, the first input terminal of the amplifier coupled to the output terminal of the differential amplifier, the second input terminal of the amplifier coupled to the voltage supply terminal, and the first output terminal of the amplifier coupled to the second input terminal of the differential amplifier.

11. The circuit of claim 10, wherein a value of an output signal provided at the second output terminal of the amplifier quantifies an effect of the stress on the first electrical component.

12. The circuit of claim 8, wherein the measurement circuit comprises:
a first switch having first and second terminals, the first terminal of the first switch coupled to a first terminal of the first electrical component and the second terminal of the first switch coupled to a second terminal of the first electrical component, wherein a second terminal of the first electrical component is coupled to a ground terminal;
a second switch having first and second terminals, the first terminal of the second switch coupled to a first terminal of the second electrical component and the second terminal of the second switch coupled to a second terminal of the second electrical component, wherein a second terminal of the second electrical component is coupled to the ground terminal;
a resistor; having first and second terminals, the second terminal of the resistor coupled to the first terminal of the second electrical component;
a first transistor having a control terminal and first and second terminals, the first terminal of the first transistor coupled to the control terminal of the first transistor, and the second terminal of the first transistor coupled to the first terminal of the first electrical component;
a second transistor having a control terminal and first and second terminals, the control terminal of the second transistor coupled to the control terminal of the first transistor, and the second terminal of the second transistor coupled to the first terminal of the resistor;
a third transistor having a control terminal and first and second terminals, the control terminal of the third transistor coupled to the first terminal of the second transistor, and the first terminal of the third transistor coupled to the control terminal of the first transistor;
a fourth transistor having a control terminal and first and second terminals, the control terminal of the fourth transistor coupled to the control terminal of the third transistor, the first terminal of the fourth transistor coupled to the first terminal of the second transistor, and the second terminal of the fourth transistor coupled to the second terminal of the third transistor; and
a fifth transistor having a control terminal and first and second terminals, the control terminal of the fifth transistor coupled to the control terminal of the fourth transistor, and the second terminal of the fifth transistor coupled to the second terminal of the fourth transistor.

13. The circuit of claim 12, wherein a value of a signal provided at the first terminal of the fifth transistor quantifies an effect of the stress on the first electrical component.

14. The circuit of claim 8, further comprising a trim circuit coupled to the measurement circuit, the first electrical component, and the second electrical component.

15. The circuit of claim 14, further comprising:
a current source having first and second terminals;
a first switch having first and second terminals, the second terminal of the first switch coupled to the second terminal of the current source; and
a second switch having first and second terminals, the first terminal of the second switch coupled to the second terminal of the current source,
wherein the first electrical component is a first resistor having first and second terminals, the first terminal of the first resistor coupled to the first terminal of the first switch, and the second terminal of the first resistor coupled to a ground terminal, and
wherein the second electrical component is a second resistor having first and second terminals, the first terminal of the second resistor coupled to the second terminal of the second switch, and the second terminal of the second resistor coupled to the ground terminal.

16. A method, comprising:
disposing a first electrical component in a first region of a substrate;
disposing a second electrical component in a second region of the substrate proximate to the first region;
disposing a measurement circuit coupled to at least one of the first electrical component or the second electrical component; and
disposing a stress induction device on the substrate above the first region.

17. The method of claim 16, wherein the measurement circuit is a first measurement circuit disposed proximate to the first electrical component and coupled to the first electrical component, the method further comprising:
disposing a second measurement circuit proximate to the second electrical component, the second measurement circuit coupled to the second electrical component.

18. The method of claim 16, further comprising:
disposing a trim circuit on the substrate, the trim circuit coupled to the measurement circuit;
determining an effect of stress on the first electrical component based on a comparison of output signals of the first and second electrical components;
determining a stress compensation for the first electrical component; and
applying, via the trim circuit, the stress compensation to the first electrical component.

19. The method of claim 16, wherein the first and second electrical components are each semiconductor devices.

20. The method of claim 16, wherein the stress induction device includes one or more of a bond wire, a bond pad, a via, or metallization.
